(19) United States
(12) Patent Application Publication
(10) Pub. No.: US 2024/0335913 A1
(43) Pub. Date: Oct. 10, 2024

(54) BONDING APPARATUS AND BONDING METHOD

(71) Applicant: Tokyo Electron Limited, Tokyo (JP)

(72) Inventor: Tetsuya Maki, Koshi City (JP)

(21) Appl. No.: 18/624,279

(22) Filed: Apr. 2, 2024

(30) Foreign Application Priority Data
Apr. 4, 2023 (JP) 2023-060600

(51) Int. Cl. B23K 37/04; B23K 31/12

(52) U.S. Cl. CPC B23K 37/04; B23K 31/12

(57) ABSTRACT

A bonding apparatus includes a first holder configured to attract and hold a first substrate from above; a second holder located lower than the first holder and configured to attract and hold a second substrate from below; a moving mechanism configured to allow a first one of the first holder and the second holder to approach a second one of the first holder and the second holder; a rough adjustment device configured to roughly adjust a position in a rotational direction of the first substrate before the first substrate is attracted and held by the first holder; a fine adjustment device, including at least one first driver configured to rotate the first holder by displacing a piezoelectric element, configured to finely adjust, with the at least one first driver, the position in the rotational direction of the first substrate attracted and held by the first holder.

### CROSS-REFERENCE TO RELATED APPLICATION

This application claims the benefit of Japanese Patent Application No. 2023-060600 filed on Apr. 4, 2023, the entire disclosure of which is incorporated herein by reference.

### TECHNICAL FIELD

The various aspects and embodiments described herein pertain generally to a bonding apparatus and a bonding method.

### BACKGROUND

Conventionally, there is known a bonding apparatus for bonding substrates such as semiconductor wafers (see, for example, Patent Document 1).
Patent Document 1: Japanese Patent Laid-open Publication No. 2018-147944

### SUMMARY

In one exemplary embodiment, a bonding apparatus includes a first holder, a second holder, a moving mechanism, a rough adjustment device and a fine adjustment device. The first holder is configured to attract and hold a first substrate from above. The second holder is located lower than the first holder and is configured to attract and hold a second substrate from below. The moving mechanism is configured to allow a first one of the first holder and the second holder to approach a second one of the first holder and the second holder. The rough adjustment device is configured to roughly adjust a position in a rotational direction of the first substrate before the first substrate is attracted and held by the first holder. The fine adjustment device includes at least one first driver configured to rotate the first holder by displacing a piezoelectric element and is configured to finely adjust, with the at least one first driver, the position in the rotational direction of the first substrate attracted and held by the first holder.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

In the detailed description that follows, exemplary embodiments are described as illustrations only since various changes and modifications will become apparent to those skilled in the art from the following detailed description. The use of the same reference numerals in different figures indicates similar or identical items.

FIG. 1 is a schematic diagram illustrating a configuration of a bonding system according to an exemplary embodiment;

FIG. 2 is a schematic diagram illustrating a state before a first substrate and a second substrate are bonded according to the exemplary embodiment;

FIG. 3 is a schematic diagram illustrating a configuration of a bonding apparatus according to the exemplary embodiment;

FIG. 4 is a schematic cross-sectional view illustrating a first holder, a fine adjustment device, and a driving device according to the exemplary embodiment;

FIG. 5 is a schematic diagram illustrating an arrangement of first drivers according to the exemplary embodiment;

FIG. 6 is a flowchart illustrating processes of processings performed by the bonding system according to the exemplary embodiment;

FIG. 7 is a flowchart illustrating an example of a specific sequence of processings corresponding to a process S106;

FIG. 8 is a schematic diagram illustrating an operation example of the bonding system according to the exemplary embodiment;

FIG. 9 is a schematic diagram illustrating an operation example of the bonding system according to the exemplary embodiment;

FIG. 10 is a schematic diagram illustrating an operation example of the bonding system according to the exemplary embodiment; and

FIG. 11 is a schematic diagram illustrating an operation example of the bonding system according to the exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other exemplary embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

The following exemplary embodiments are examples for describing the present disclosure, and the present disclosure is not limited thereto. In the following description, same parts or parts having same function will be assigned same reference numerals, and redundant description will be omitted.

Hereinafter, embodiments for a bonding apparatus and a bonding method according to the present disclosure (hereinafter, referred to as “exemplary embodiments”) will be described in detail with reference to the accompanying drawings. Further, it should be noted that the present disclosure is not limited by the exemplary embodiments. Further, unless processing contents are contradictory, the various exemplary embodiments can be appropriately combined. Furthermore, in the various exemplary embodiments to be described below, same parts will be assigned same reference numerals, and redundant description will be omitted.

Further, in the following exemplary embodiments, expressions such as “constant,” “perpendicular,” “vertical” and “parallel” may be used. These expressions, however, do not imply strictly “constant”, “perpendicular,” “vertical” and “parallel”. That is, these expressions allow some tolerable errors in, for example, manufacturing accuracy, installation accuracy, or the like.

Moreover, in the various accompanying drawings, for the purpose of clear understanding, there may be used a rectangular coordinate system in which the X-axis direction, Y-axis direction and Z-axis direction which are orthogonal to one another are defined and the positive Z-axis direction is defined as a vertically upward direction. Further, a rotational direction around a vertical axis may be referred to as “θ direction.”

In a bonding apparatus configured to bond substrates, positioning of the substrates in a rotational direction is performed before the substrates are bonded. Improvement of this positioning accuracy in the rotational direction leads to improvement of bonding accuracy for the substrates. Thus, in the bonding apparatus, it is required to improve the bonding accuracy for the substrates by improving the positioning accuracy for the substrates in the rotational direction.

### <Configuration of Bonding System>

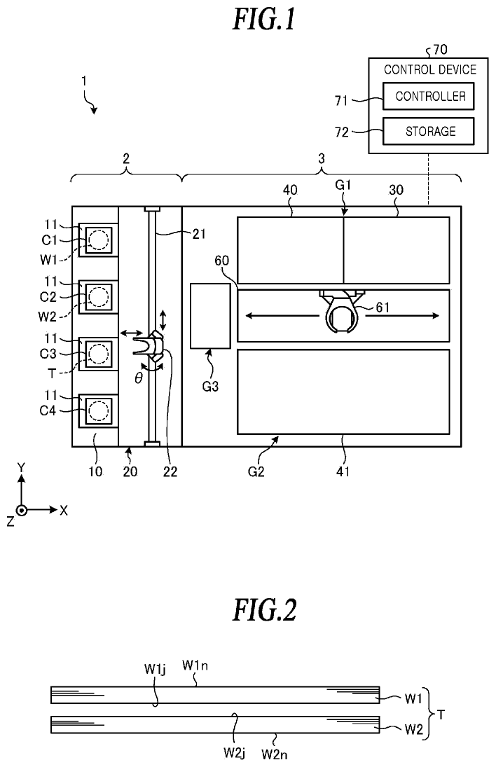

First, a configuration of a boding system according to an exemplary embodiment will be described with reference to FIG. 1 and FIG. 2. FIG. 1 is a schematic diagram illustrating the configuration of the bonding system according to the exemplary embodiment. FIG. 2 is a schematic diagram illustrating a state of a first substrate and a second substrate before they are bonded according to the exemplary embodiment.

A bonding system 1 shown in FIG. 1 is configured to form a combined substrate T by bonding a first substrate W1 and a second substrate W2 (see FIG. 2). The bonding system 1 is an example of a bonding apparatus.

The first substrate W1 and the second substrate W2 are single crystalline silicon wafers, and a multiple number of electronic circuits are formed on their plate surfaces. The first substrate W1 and the second substrate W2 have the substantially same diameter. Alternatively, either one of the first substrate W1 and the second substrate W2 may be a substrate on which no electronic circuit is formed.

In the following description, as shown in FIG. 2, among plate surfaces of the first substrate W1, a plate surface to be bonded to the second substrate W2 will be referred to as “bonding surface W1j”, and a plate surface opposite to the bonding surface W1j will be referred to as “non-bonding surface W1n”. Further, among plate surfaces of the second substrate W2, a plate surface to be bonded to the first substrate W1 will be referred to as “bonding surface W2j”, and a plate surface opposite to the bonding surface W2j will be referred to as “non-bonding surface W2n”.

As depicted in FIG. 1, the bonding system 1 includes a carry-in/out station 2 and a processing station 3. The carry-in/out station 2 is disposed on the negative X-axis side of the processing station 3, and is connected as a single body with the processing station 3.

The carry-in/out station 2 includes a placing table 10 and a transfer section 20. The placing table 10 is equipped with a multiple number of placing plates 11. Respectively provided on the placing plates 11 are cassettes C1 to C4 each of which accommodates therein a plurality of (e.g., 25 sheets of) substrates horizontally. The cassette C1 accommodates therein a plurality of first substrates W1; the cassette C2, a plurality of second substrates W2; and the cassette C3, a plurality of combined substrates T. The cassette C4 is a cassette for collecting, for example, a defective substrate. Further, the number of the cassettes C1 to C4 placed on the placing plates 11 is not limited to the shown example.

The transfer section 20 is provided adjacent to the positive X-axis side of the placing table 10. Provided in the transfer section 20 are a transfer path 21 extending in the Y-axis direction and a transfer device 22 configured to be movable along the transfer path 21. The transfer device 22 is configured to be movable in the X-axis direction as well as in the Y-axis direction and pivotable around the Z-axis. The transfer device 22 transfers the first substrates W1, the second substrates W2, and the combined substrates T between the cassettes C1 to C4 placed on the placing plates 11 and a third processing block G3 of the processing station 3 to be described later.

The processing station 3 is provided with, for example, three processing blocks G1, G2 and G3. The first processing block G1 is disposed on the rear side (positive Y-axis side of FIG. 1) of the processing station 3. Further, the second processing block G2 is provided on the front side (negative Y-axis side of FIG. 1) of the processing station 3, and the third processing block G3 is disposed on the carry-in/out station 2 side (negative X-axis side of FIG. 1) of the processing station 3.

Disposed in the first processing block G1 is a surface modifying apparatus 30 configured to modify the bonding surface W1j of the first substrate W1 and the bonding surface W2j of the second substrate W2. The surface modifying apparatus 30 cuts a SiO₂ bond on the bonding surfaces W1j and W2j of the first and second substrates W1 and W2 into a single bond of SiO, thus allowing the bonding surfaces W1j and W2j to be modified so that they are easily hydrophilized afterwards.

Specifically, in the surface modifying apparatus 30, an oxygen gas or a nitrogen gas as a processing gas is excited into plasma under, for example, a decompressed atmosphere to be ionized. As these oxygen ions or nitrogen ions are radiated to the bonding surfaces W1j and W2j of the first and second substrates W1 and W2, the bonding surfaces W1j and W2j are modified by being plasma-processed.

Further, in the first processing block G1, a surface hydrophilizing apparatus 40 is disposed. The surface hydrophilizing apparatus 40 is configured to hydrophilize and clean the bonding surfaces W1j and W2j of the first and second substrates W1 and W2 with, for example, pure water. To elaborate, the surface hydrophilizing apparatus 40 supplies the pure water onto the first substrate W1 or the second substrate W2 while rotating the first substrate W1 or the second substrate W2 held by, for example, a spin chuck. Accordingly, the pure water supplied onto the first substrate W1 or the second substrate W2 is diffused on the bonding surface W1j of the first substrate W1 or the bonding surface W2j of the second substrate W2, so that the bonding surfaces W1j and W2j are hydrophilized.

Here, although the surface modifying apparatus 30 and the surface hydrophilizing apparatus 40 are arranged side by side, the surface hydrophilizing apparatus 40 may be stacked on top of or under the surface modifying apparatus 30.

In the second processing block G2, a bonding apparatus 41 is disposed. The boning apparatus 41 is configured to bond the hydrophilized first and second substrates W1 and W2 by an intermolecular force. A specific configuration of the bonding apparatus 41 will be described later.

In the third processing block G3, a transition device (not shown) for the first substrate W1, the second substrate W2, and the combined substrate T is provided.

A transfer section 60 is formed in a region surrounded by the first processing block G1, the second processing block G2, and the third processing block G3. A transfer device 61 is disposed in the transfer section 60. The transfer device 61 has a transfer arm configured to be movable in a vertical direction and a horizontal direction and pivotable around a vertical axis, for example. This transfer device 61 is moved within the transfer section 60 and transfers the first substrate W1, the second substrate W2 and the combined substrate T to preset apparatuses within the first processing block G1, the second processing block G2, and the third processing block G3 which are adjacent to the transfer section 60.

Furthermore, the bonding system 1 is equipped with a control device 70. The control device 70 controls an operation of the bonding system 1. This control device 70 may be implemented by, for example, a computer, and includes a controller 71 and a storage 72. The controller 71 includes a microcomputer having a CPU (Central Processing Unit), a ROM (Read Only Memory), a RAM (Random Access Memory), an input/output port, and so forth as well as various kinds of circuits. The CPU of the microcomputer implements a control to be described later by reading out and executing a program stored in the ROM. Further, the storage 72 may be implemented by, for example, a semiconductor memory device such as a RAM or a flash memory, or a storage device such as a hard disk or an optical disk.

Further, the program may have been recorded on a computer-readable recording medium, and may be installed from the recording medium to the storage 72 of the control device 70. The computer-readable recording medium may be, by way of non-limiting example, a hard disk HD, a flexible disk FD, a compact disk CD, a magnetic optical disk MO, a memory card, or the like.

### <Configuration of Bonding Apparatus>

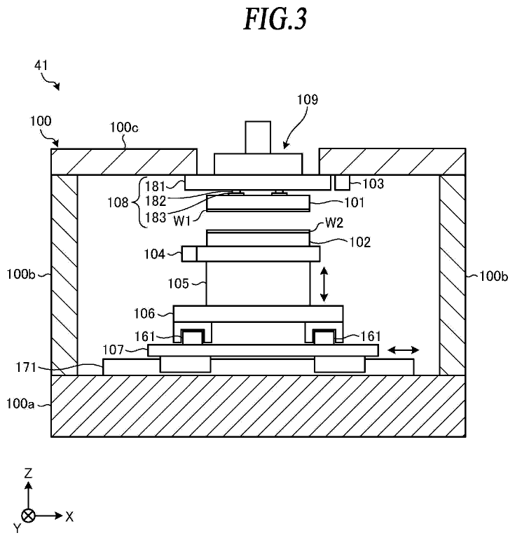

Now, a configuration of the bonding apparatus 41 will be explained with reference to FIG. 3. FIG. 3 is a schematic diagram illustrating the configuration of the bonding apparatus 41 according to the exemplary embodiment.

As depicted in FIG. 3, the bonding apparatus 41 includes a housing 100, a first holder 101, and a second holder 102. The bonding apparatus 41 is further equipped with an upper imaging device 103 and a lower imaging device 104. Further, the bonding apparatus 41 additionally includes an elevating mechanism 105 (an example of a moving mechanism), a first horizontally moving device 106, a second horizontally moving device 107, a fine adjustment device 108, and a driving device 109.

The housing 100 includes, for example, a base 100a, a plurality of supporting columns 100b standing on the base 100a, and a beam member 100c put on the plurality of supporting columns 100b.

The first holder 101 is, for example, a vacuum chuck, and is connected to a non-illustrated suction device such as a vacuum pump. The first holder 101 is configured to attract and hold the first substrate W1 from above by suctioning the first substrate W1 positioned on an attraction surface (bottom surface of the first holder 101) with a suction force generated by the suction device. A specific configuration of the first holder 101 will be described later.

The second holder 102 is, for example, a vacuum chuck, and is connected to a non-illustrated suction device such as a vacuum pump. The second holder 102 is configured to attract and hold the second substrate W2 from below by suctioning the second substrate W2 with a suction force generated by the suction device.

The upper imaging device 103 is configured to image the top surface (bonding surface W2j) of the second substrate W2 held by the second holder 102. The upper imaging device 103 is mounted to the beam member 100c of the housing 100, for example. The upper imaging device 103 may be implemented by, for example, a CCD (Charge Coupled Device) camera or the like.

The lower imaging device 104 is configured to image the bottom surface (bonding surface W1j) of the first substrate W1 held by the first holder 101. The lower imaging device 104 is mounted to a lateral side of the elevating mechanism 105, for example. The lower imaging device 104 may be implemented by, by way of non-limiting example, a CCD camera or the like.

The second holder 102 is fixed to the elevating mechanism 105 provided below the second holder 102. The elevating mechanism 105 is configured to move the second holder 102 along the vertical direction (Z-axis direction).

The elevating mechanism 105 is fixed to the first horizontally moving device 106 provided below the elevating mechanism 105. The first horizontally moving device 106 is configured to move the elevating mechanism 105 along a horizontal direction. Specifically, a pair of rails 161 extending along the Y-axis direction are provided under the first horizontally moving device 106, and the first horizontally moving device 106 is moved along the pair of rails 161, thus allowing the elevating mechanism 105 to be moved along the Y-axis direction.

The pair of rails 161 are fixed to the second horizontally moving device 107. The second horizontally moving device 107 is configured to move the first horizontally moving device 106 along a horizontal direction via the pair of rails 161. To elaborate, a pair of rails 171 extending along the X-axis direction are provided under the second horizontally moving device 107. The second horizontally moving device 107 is moved along the pair of rails 171, thus allowing the first horizontally moving device 106 to be moved along the X-axis direction via the pair of rails 161. The pair of rails 171 are fixed to the base 100a of the housing 100.

The first holder 101 is fixed to the fine adjustment device 108 provided above the first holder 101. The fine adjustment device 108 is configured to rotate the first holder 101 around a vertical axis (Z axis), whereby the position of the first substrate W1 held by the first holder 101 in the θ direction is adjusted.

The fine adjustment device 108 includes a base member 181, a plurality of column members 182 fixed to the base member 181, and a plurality of first drivers 183 fixed to one ends of the column members 182 and configured to rotate the first holder 101 around a vertical axis.

The base member 181 is, for example, a flat plate-shaped member, and fixed to the beam member 100c of the housing 100. The base member 181 is provided with a through hole 181a that is formed through the base member 181 in the vertical direction. The through hole 181a has a greater diameter than a cylindrical member 192a of a third holder 192 to be described later. The cylindrical member 192a of the third holder 192 is inserted through the through hole 181a.

The plurality of column members 182 extends in the vertical direction and is provided on a lower surface of the base member 181. The first holder 101 is fixed to a lower surface of a flange member 181b.

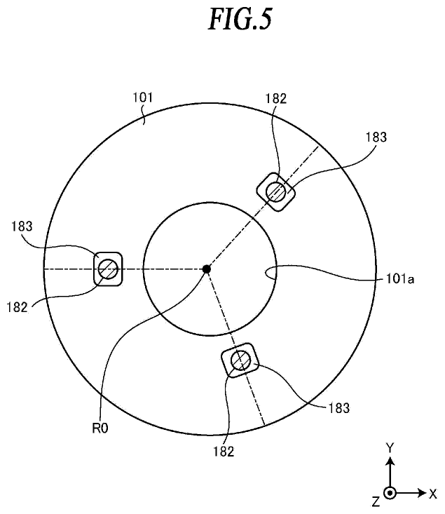

The plurality of first drivers 183 is fixed to one ends (lower ends) of the column members 182. The first holder 101 is located under the first drivers 183. The plurality of first drivers 183 is, for example, a piezoelectric stage. In the exemplary embodiment, the fine adjustment device 108 includes three first drivers 183 (see FIG. 5 to be described later).

The first driver 183 uses a piezoelectric effect to displace a piezoelectric element and thus finely drive the first holder 101. Specifically, the first driver 183 displaces the first holder 101 in a circumferential direction of the first holder 101. The amount of displacement of the first holder 101 by the first driver 183 is, for example, about ±2 μm, and is smaller than that of the third holder 192 by a rough adjustment device 194 to be described later.

The fine adjustment device 108 is configured as described above, and controls the first driver 183 to finely adjust a position in the rotational direction of the first substrate W1 attracted and held by the first holder 101. The bonding system 1 according to the exemplary embodiment can achieve high responsiveness and static balance by using the first driver 183 including the piezoelectric element even when, for example, the first substrate W1 is rotated at a nanometer level.

In the bonding system 1 according to the exemplary embodiment, the position of the first substrate W1 in the rotational direction is roughly adjusted and finely adjusted respectively in separate mechanisms. Specifically, the bonding system 1 includes the rough adjustment device configured to adjust the position of the first substrate W1 in the rotational direction before the first substrate W1 is attracted and held by the first holder 101, and the above-described fine adjustment device 108. Thus, the position of the first substrate W1 in the rotational direction may be roughly adjusted, and then, finely adjusted by using the first driver 183 with high accuracy. Therefore, it is possible to improve the positioning accuracy for the first substrate W1 in the rotational direction and thus possible to improve the bonding accuracy for the combined substrate T.

In the exemplary embodiment, the rough adjustment device is provided in the driving device 109. The driving device 109 is placed, for example, on the base member 181 of the fine adjustment device 108. The driving device 109 includes a striker configured to press a central portion of the first substrate W1 held by the first holder 101, the third holder configured to attract and hold the first substrate W1 from the transfer device 61 and transfer the first substrate W1 to the first holder 101, and the rough adjustment device configured to roughly adjust the position of the first substrate W1 in the rotational direction. A specific configuration of the driving device 109 will be discussed later.

Further, although not shown here, the bonding apparatus 41 is equipped with a transition device, a position adjusting mechanism, an inverting mechanism, and so forth at a leading end of the first holder 101 or the second holder 102 shown in FIG. 3. The transition device is configured to temporarily accommodate therein the first substrate W1, the second substrate W2, and the combined substrate T. The position adjusting mechanism is configured to adjust the directions of the first substrate W1 and the second substrate W2 in the horizontal direction. The inverting mechanism is configured to invert the front and rear surfaces of the first substrate W1.

### <Configuration of First Holder>

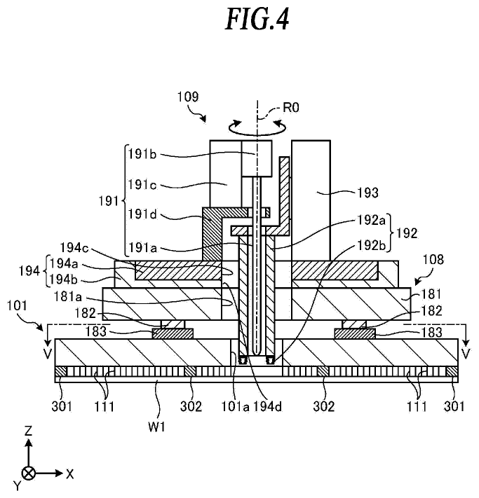

Now, a configuration example of the first holder 101 will be explained will be discussed with reference to FIG. 4. FIG. 4 is a schematic cross sectional view of the first holder 101, the fine adjustment device 108, and the driving device 109 according to the exemplary embodiment.

As shown in FIG. 4, a plurality of pins 111 are provided on the bottom surface of the first holder 101 to be in contact with the top surface (non-bonding surface W1n) of the first substrate W1. The plurality of pins 111 have a diameter ranging from, e.g., 0.1 mm to 1 mm and a height of, e.g., several tens to hundreds of μm. The plurality of pins 111 are evenly arranged at a distance of, e.g., 2 mm.

In addition, a plurality of outer attraction members 301 and a plurality of inner attraction members 302 are provided on the bottom surface of the first holder 101 to attract the first substrate W1 by evacuation. Each of the plurality of outer attraction members 301 and the plurality of inner attraction members 302 has, for example, an arc-shaped attraction region when viewed from the top. Further, the plurality of outer attraction members 301 and the plurality of inner attraction members 302 have the same height as the pins 111. The outer attraction members 301 are arranged at an outer peripheral portion of the first holder 101 along a circumferential direction thereof. The inner attraction portions 302 are arranged along the circumferential direction at an inner side than the plurality outer attraction portions 301 in a radial direction of the first holder 101.

A through hole 101a is formed through a central portion of the first holder 101 in a vertical direction. A cylindrical member 192a to be described later is inserted into this through hole 101a.

### <Configuration of Driving Device>

Hereinafter, a configuration of the driving device 109 will be described with reference to FIG. 4. As shown in FIG. 4, the driving device 109 includes a striker 191, the third holder 192, a linearly moving mechanism 193, and the rough adjustment device 194.

The striker 191 includes a push pin 191a, an actuator device 191b, a linearly moving mechanism 191c, and a supporting member 191d. The push pin 191a is a columnar member extending along the vertical direction and is inserted through the inside of the cylindrical member 192a to be described later. In other words, the push pin 191a is inserted through the through hole formed in the third holder 192 to be described later. The push pin 191a is supported by the actuator device 191b.

The actuator device 191b is configured to generate a constant pressure in a certain direction (herein, a vertically downward direction) by air supplied from, for example, an electro-pneumatic regulator (not shown). By the air supplied from the electro-pneumatic regulator, the actuator device 191b is capable of controlling a press load applied to the central portion of the first substrate W1 as it is brought into contact with the central portion of the first substrate W1. The linearly moving mechanism 191c is configured to support the actuator device 191b. Also, the linearly moving mechanism 191c is configured to move the actuator device 191b in the vertical direction by using a driver including, for example, a motor. The supporting member 191d is provided, for example, on an upper surface of a rotary table 194a in the rough adjustment device 194 to be described later, and configured to support the linearly moving mechanism 191c to be spaced apart from the rotary table 194a.

The striker 191 is configured as described above, and controls a movement of the actuator device 191b by using the linearly moving mechanism 191c and controls the press load onto the first substrate W1 from the push pin 191a by using the actuator device 191b. Thus, the striker 191 presses the central portion of the first substrate W1 attracted and held by the first holder 101 to allow the first substrate W1 to come into contact with the second substrate W2.

The third holder 192 includes the cylindrical member 192a and a plurality of attraction members 192b. The cylindrical member 192a is a cylinder-shaped member and is inserted through the through hole 101a formed through the first holder 101. The plurality of attraction members 192b is provided at a leading end of the cylindrical member 192a. The plurality of attraction members 192b attracts the first substrate W1 by evacuation.

The linearly moving mechanism 193 holds the third holder 192. Further, the linearly moving mechanism 193 moves the third holder 192 in the vertical direction by using a driver including, for example, a motor.

The third holder 192 receives the first substrate W1 from a non-illustrated inverting mechanism included in the bonding apparatus 41 by using the attraction members 192b. Then, the linearly moving mechanism 193 raises the cylindrical member 192a to transfer the first substrate W1 to the first holder 101.

The rough adjustment device 194 includes the rotary table 194a configured to rotate the first substrate W1 around a vertical axis, and a supporting table 194b configured to support the rotary table 194a to be rotatable.

The linearly moving mechanism 193 is provided on the rotary table 194a. The rotary table 194a operates to be rotatable around the vertical axis by a non-illustrated driver (an example of a second driver). A rotation axis of the rotary table 194a is aligned with a central axis R0 of the cylindrical member 192a of the third holder 192. That is, the rotary table 194a rotates around the central axis R0 of the cylindrical member 192a. Also, the cylindrical member 192a rotates around the central axis R0. Accordingly, the first substrate W1 attracted and held by the attraction members 192b rotates around the central axis R0.

A through hole 194c that is formed through the rotary table 194a in the vertical direction is formed in a central portion of the rotary table 194a. The cylindrical member 192a of the third holder 192 is inserted through the through hole 194c. Likewise, a through hole 194d that is formed through the supporting table 194b in the vertical direction is formed in a central portion of the supporting table 194b. The cylindrical member 192a of the third holder 192 is inserted through the through hole 194d.

The rough adjustment device 194 is configured as described above, and rotates the rotary table 194a by using a non-illustrated driver, and thus, rotates the linearly moving mechanism 193 and the third holder 192 held by the linearly moving mechanism 193 around the vertical axis. Thus, the position in the rotational direction of the first substrate W1 attracted and held by the third holder 192 is roughly adjusted.

Herein, the “rough adjustment” refers to an adjustment with lower accuracy than fine adjustment. Also, the rough adjustment may have a wider adjustment range for a first level than the fine adjustment. Further, the rough adjustment may have a wider adjustable range than the fine adjustment.

### <Arrangement of First Drivers>

Hereinafter, an arrangement of the first drivers 183 will be described with reference to FIG. 5. FIG. 5 is a schematic diagram illustrating an arrangement of the first drivers 183 according to the exemplary embodiment. Also, FIG. 5 is a cross-sectional view taken along a line V-V in FIG. 4.

As shown in FIG. 5, three first drivers 183 are uniformly arranged at an angular distance of 120 degrees therebetween in the circumferential direction of the first holder 101. Accordingly, a force is uniformly applied in the circumferential direction of the first holder 101, and, thus, the positioning of the first substrate W1 can be performed with high accuracy.

The three first drivers 183 are arranged such that a displacement direction of the first holder 101 corresponds to the circumferential direction of the first holder 101. Specifically, the three first drivers are arranged to displace the first holder 101 in a direction orthogonal to the diametrical direction of the first holder 101 (a direction indicated by a dashed-dotted line in FIG. 5) when viewed from the top. In an example shown in FIG. 5, the bonding apparatus 41 includes the three first drivers 183. However, the number of the first drivers 183 is not limited to three.

### <Specific Operation of Bonding System>

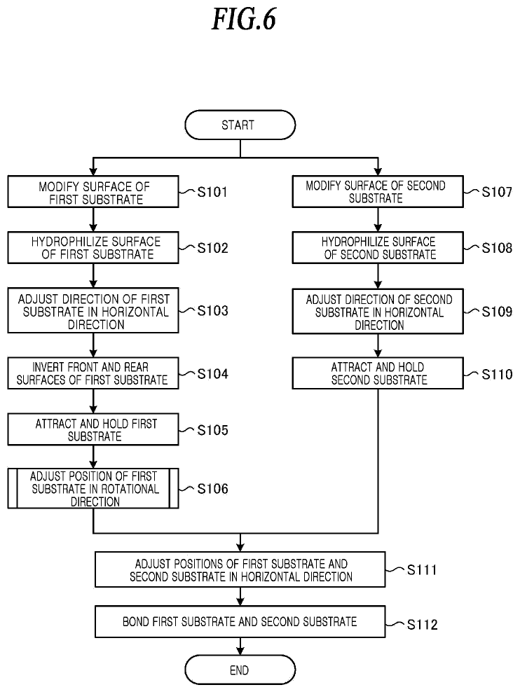

Now, a specific operation of the bonding system 1 will be explained with reference to FIG. 6. FIG. 6 is a flowchart showing a sequence of processings performed by the bonding system 1 according to the exemplary embodiment. Various processings shown in FIG. 6 are performed based on a control by the control device 70.

First, the cassette C1 accommodating the plurality of first substrates W1, the cassette C2 accommodating the plurality of second substrates W2, and the empty cassette C3 are placed on the preset placing plates 11 of the carry-in/out station 2. Then, the first substrate W1 is taken out from the cassette C1 by the transfer device 22, and transferred into a transition device disposed within the third processing block G3.

Then, the first substrate W1 is transferred to the surface modifying apparatus 30 of the first processing block G1 by the transfer device 61. In the surface modifying apparatus 30, an oxygen gas as a processing gas is excited into plasma to be ionized under a preset decompressed atmosphere. Oxygen ions are radiated to the bonding surface of the first substrate W1, so that the bonding surface is plasma-processed. As a result, the bonding surface of the first substrate W1 is modified (process S101).

Subsequently, the first substrate W1 is transferred to the surface hydrophilizing apparatus 40 of the first processing block G1 by the transfer device 61. In the surface hydrophilizing apparatus 40, pure water is supplied onto the first substrate W1 while rotating the first substrate W1 held by the spin chuck. As a result, the bonding surface of the first substrate W1 is hydrophilized. Further, the bonding surface of the first substrate W1 is cleaned by this pure water (process S102).

Next, the first substrate W1 is transferred to the bonding apparatus 41 of the second processing block G2 by the transfer device 61. The first substrate W1 carried into the bonding apparatus 41 is then transferred into the position adjusting mechanism via the transition, and the direction of the first substrate W1 in the horizontal direction is adjusted by the position adjusting mechanism (process S103).

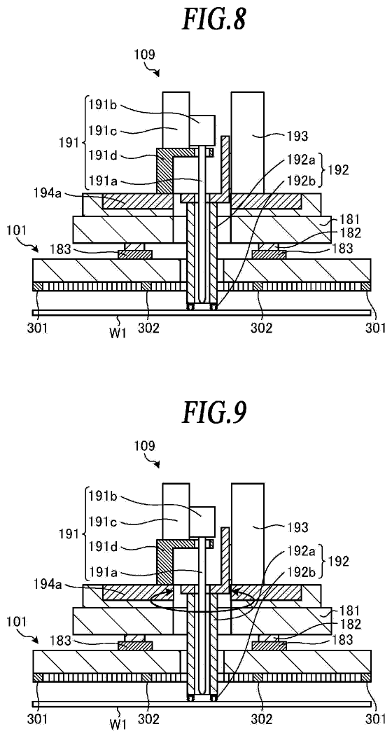

Subsequently, the first substrate W1 is delivered from the position adjusting mechanism to the inverting mechanism, and then the front surface and the rear surface of the first substrate W1 are inverted by the inverting mechanism (process S104). Specifically, the bonding surface W1j of the first substrate W1 is directed downwards. Then, the first substrate W1 is delivered from the inverting mechanism to the third holder 192 and then attracted and held by the third holder 192 (process S105). Specifically, the third holder 192 receives the first substrate W1 from the inverting mechanism by using the attraction members 192b. Accordingly, the first substrate W1 is attracted and held by the third holder 192 (see FIG. 8).

Thereafter, the position of the first substrate W1 in the rotational direction is adjusted by using the rough adjustment device 194 and the fine adjustment device 108 (process S106). A specific sequence of the process S106 will be described later.

In parallel with the processing of the processes S101 to S106 upon the first substrate W1, a processing of the second substrate W2 is performed. First, the second substrate W2 is taken out of the cassette C2 by the transfer device 22, and transferred to the transition device disposed in the third processing block G3.

Then, the second substrate W2 is transferred to the surface modifying apparatus 30 by the transfer device 61, and the bonding surface W2j of the second substrate W2 is modified (process S107). Thereafter, the second substrate W2 is transferred to the surface hydrophilizing apparatus 40 by the transfer device 61, and the bonding surface W2j of the second substrate W2 is hydrophilized and cleaned (process S108).

Subsequently, the second substrate W2 is transferred to the bonding apparatus 41 by the transfer device 61. The second substrate W2 carried into the bonding apparatus 41 is transferred to the position adjusting mechanism via the transition. Then, the direction of the second substrate W2 in the horizontal direction is adjusted by the position adjusting mechanism (process S109).

Afterwards, the second substrate W2 is transferred to the second holder 102 to be attracted to and held by the second holder 102 with a notch thereof directed toward a predetermined direction (process S110).

Subsequently, the position adjustment between the first substrate W1 held by the first holder 101 and the second substrate W2 held by the second holder 102 in the horizontal direction is performed (process S111). Afterwards, the second substrate W2 is raised by using the elevating mechanism 105 to bond the first substrate W1 and the second substrate W2 (process S112). Specifically, after the second substrate W2 is raised, the center of the first substrate W1 is pressed downwards from above by using the pressing pin 191a of the striker 191 be brought into contact with the center of the second substrate W2, so that the first substrate W1 and the second substrate W2 are bonded too each other.

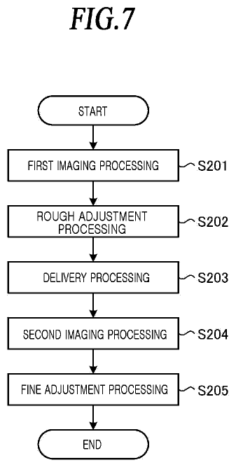

Then, an example of a specific sequence of adjusting the position of the first substrate W1 in the rotational direction in the process S106 will be described with reference to FIG. 7. FIG. 7 is a flowchart illustrating an example of a specific sequence of processings corresponding to the process S106. FIG. 8 to FIG. 11 are schematic diagrams illustrating operation examples of the bonding system 1 according to the exemplary embodiment.

As shown in FIG. 7, the controller 71 performs a first imaging processing (process S201). In the first imaging processing, the controller 71 controls the lower imaging device 104 to image the bonding surface W1j which is a non-holding surface of the first substrate W1. The controller 71 calculates a rotation angle of the first substrate W1 from an image obtained by the lower imaging device 104. The rotation angle refers to information indicative of a direction of the first substrate W1 in the horizontal direction and represents, as an angle, the deviation degree from a reference direction.

Thereafter, the controller 71 performs a rough adjustment processing (process S202). In the rough adjustment processing, the controller 71 controls the rough adjustment device 194 based on the imaging result obtained in the first imaging processing to rotate the third holder 192 (see FIG. 9). For example, the controller 71 controls the rough adjustment device 194 to rotate the third holder 192 such that the rotation angle of the first substrate W1 becomes close to a rotation angle of the second substrate W2. The rotation angle of the second substrate W2 may be calculated from the imaging result of the bonding surface W2j of the second substrate W2 obtained by the upper imaging device 103.

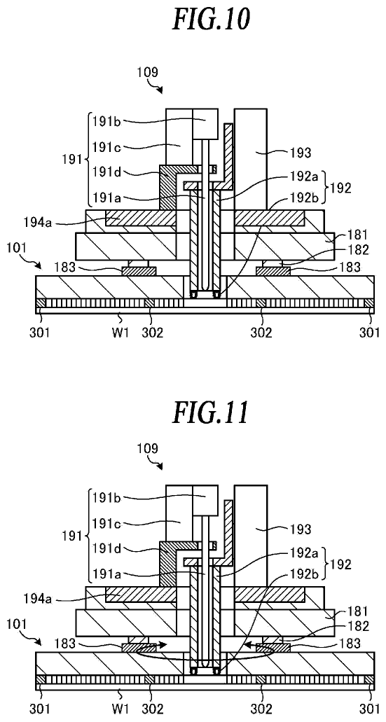

Subsequently, the controller 71 performs a delivery processing (process S203). In the delivery processing, the controller 71 controls the linearly moving mechanism 193 to raise the cylindrical member 192a and thus deliver the first substrate W1 to the first holder 101. Accordingly, the first substrate W1 is attracted and held by the first holder 101 (see FIG. 10).

Thereafter, the controller 71 performs a second imaging processing (process S204). In the second imaging processing, the controller 71 images the bonding surface W1j of the first substrate W1 by using the lower imaging device 104. The controller 71 re-calculates the rotation angle of the first substrate W1 from the image obtained by the lower imaging device 104.

Thereafter, the controller 71 performs a fine adjustment processing (process S205). In the fine adjustment processing, the controller 71 controls the first drivers 183 and displaces the piezoelectric element based on the imaging result obtained in the second imaging processing to rotate the first holder 101 (see FIG. 11). For example, the controller 71 controls the first driver 183 to finely displace the piezoelectric element such that the rotation angle of the first substrate W1 becomes equal to the rotation angle of the second substrate W2.

As described above, in the bonding system 1 according to the exemplary embodiment, the position of the first substrate W1 in the rotational direction is roughly adjusted and finely adjusted respectively in the separate mechanisms. Thus, the position of the first substrate W1 in the rotational direction may be roughly adjusted, and then, finely adjusted by using the first drivers 183 with high accuracy. Therefore, it is possible to improve the positioning accuracy for the first substrate W1 in the rotational direction, so that the bonding accuracy for the combined substrate T can be improved.

### Other Exemplary Embodiments

In the above-described exemplary embodiment, the rough adjustment device 194 including the rotary table 194a rotates the third holder 192 in the rotational direction to roughly adjust the position of the first substrate W1 in the rotational direction. However, the configuration of the rough adjustment device 194 is not limited thereto.

For example, the rough adjustment device may roughly adjust the position of the first substrate W1 in the rotational direction before the first substrate W1 is delivered to the third holder 192. In this case, the bonding system 1 may be equipped with a rough adjustment device 194 including a pre-alignment device configured to detect position information of the first substrate W1 in the rotational direction, and a transfer arm configured to roughly adjust the position of the first substrate W1 in the rotational direction based on the position information detected by the pre-alignment device and deliver the first substrate W1 to the third holder 192. In this case, the controller 71 detects the position information of the first substrate W1 by using the pre-alignment device, and roughly adjusts the position of the first substrate W1 in the rotational direction based on the detected position information and delivers the first substrate W1 to the third holder 192 by using the transfer arm.

Alternatively, the bonding system 1 may be equipped with, as the rough adjustment device, an imaging device provided inside the bonding apparatus 41 and configured to image the bonding surface W1j of the first substrate W1, and a transfer arm configured to roughly adjust the position of the first substrate W1 in the rotational direction based on the imaging result obtained by the imaging device and deliver the first substrate W1 to the third holder 192. In this case, the controller 71 images the bonding surface of the first substrate W1 by using the imaging device, and roughly adjusts the position of the first substrate W1 in the rotational direction based on the imaging result and delivers the first substrate W1 to the third holder 192 by using the transfer arm.

The present disclosure may also employ the following configurations.

(1)

A bonding apparatus, including:
a first holder configured to attract and hold a first substrate from above;
a second holder located lower than the first holder and configured to attract and hold a second substrate from below;
a moving mechanism configured to allow a first one of the first holder and the second holder to approach a second one of the first holder and the second holder;
a rough adjustment device configured to roughly adjust a position in a rotational direction of the first substrate before the first substrate is attracted and held by the first holder; and
a fine adjustment device, including at least one first driver configured to rotate the first holder by displacing a piezoelectric element, configured to finely adjust, with the at least one first driver, the position in the rotational direction of the first substrate attracted and held by the first holder.

(2)

The bonding apparatus described in (1),
wherein at least two first drivers are uniformly arranged in a circumferential direction of the first holder.

(3)

The bonding apparatus described in (1) or (2), further including:
a third holder inserted through a through hole formed through the first holder and configured to attract and hold the first substrate from above; and
a linearly moving mechanism configured to move the third holder in a vertical direction,
wherein the rough adjustment device roughly adjusts, by rotating the third holder around a vertical axis, the position in the rotational direction of the first substrate attracted and held by the third holder.

(4)

The bonding apparatus described in (3),
wherein the rough adjustment device includes a rotary table on which the linearly moving mechanism is provided and a second driver configured to rotate the rotary table around the vertical axis, and
the linearly moving mechanism and the third holder held by the linearly moving mechanism are rotated around the vertical axis by rotating the rotary table with the second driver.

(5)

The bonding apparatus described in (3) or (4), further including:
a striker inserted through a through hole formed through the third holder, and configured to press a central portion of the first substrate to allow the first substrate to come into contact with the second substrate.

(6)

The bonding apparatus described in any one of (3) to (5), including:
an imaging device configured to image a bonding surface of the first substrate; and
a controller,
wherein the controller performs a first imaging processing in which the bonding surface of the first substrate held by the third holder is imaged with the imaging device; a rough adjustment processing in which the third holder is rotated by controlling the rough adjustment device based on an imaging result obtained in the first imaging processing; a delivery processing in which the first substrate is delivered to the first holder by controlling the linearly moving mechanism to raise the third holder after the rough adjustment processing; a second imaging processing in which the bonding surface of the first substrate held by the first holder is imaged with the imaging device after the delivery processing; and a fine adjustment processing in which the first holder is rotated by controlling the at least one first driver based on an imaging result obtained in the second imaging processing after the second imaging processing.

(7)

The bonding apparatus described in (1),
wherein the rough adjustment device includes:
a pre-alignment device configured to detect position information in the rotational direction of the first substrate before the first substrate is attracted and held by the first holder; and
a transfer arm configured to roughly adjust the position in the rotational direction of the first substrate based on the position information detected by the pre-alignment device.

(8)

The bonding apparatus described in (1),
wherein the rough adjustment device includes:
an imaging device configured to image a bonding surface of the first substrate before the first substrate is attracted and held by the first holder; and
a transfer arm configured to roughly adjust the position in the rotational direction of the first substrate based on an imaging result obtained by the imaging device.

(9)

A bonding method, including:
attracting and holding a first substrate from above by using a first holder configured to attract and hold the first substrate from above;
attracting and holding a second substrate from below by using a second holder located lower than the first holder and configured to attract and hold the second substrate from below;
allowing, by using a moving mechanism configured to allow a first one of the first holder and the second holder to approach a second one of the first holder and the second holder, the first one of the first holder and the second holder to approach the second one of the first holder and the second holder;
roughly adjusting a position in a rotational direction of the first substrate before the first substrate is attracted and held by the first holder; and
finely adjusting the position in the rotational direction of the first substrate attracted and held by the first holder by using at least one first driver configured to drive the first holder by displacing a piezoelectric element.

It should be noted that the above-described exemplary embodiments are illustrative in all aspects and are not anyway limiting. In fact, the above-described exemplary embodiments can be embodied in various forms. Further, the above-described exemplary embodiments may be omitted, replaced and modified in various ways without departing from the scope and the spirit of claims.

According to the exemplary embodiment, it is possible to improve the bonding accuracy for the combined substrate.

From the foregoing, it will be appreciated that various exemplary embodiments of the present disclosure have been described herein for purposes of illustration and various changes can be made without departing from the scope and spirit of the present disclosure. Accordingly, various exemplary embodiments described herein are not intended to be limiting, and the true scope and spirit are indicated by the following claims.

We claim:

1. A bonding apparatus, comprising:
a first holder configured to attract and hold a first substrate from above;
a second holder located lower than the first holder and configured to attract and hold a second substrate from below;
a moving mechanism configured to allow a first one of the first holder and the second holder to approach a second one of the first holder and the second holder;
a rough adjustment device configured to roughly adjust a position in a rotational direction of the first substrate before the first substrate is attracted and held by the first holder; and
a fine adjustment device, including at least one first driver configured to rotate the first holder by displacing a piezoelectric element, configured to finely adjust, with the at least one first driver, the position in the rotational direction of the first substrate attracted and held by the first holder.

2. The bonding apparatus of claim 1,
wherein at least two first drivers are uniformly arranged in a circumferential direction of the first holder.

3. The bonding apparatus of claim 1, further comprising:
a third holder inserted through a through hole formed through the first holder and configured to attract and hold the first substrate from above; and
a linearly moving mechanism configured to move the third holder in a vertical direction,
wherein the rough adjustment device roughly adjusts, by rotating the third holder around a vertical axis, the position in the rotational direction of the first substrate attracted and held by the third holder.

4. The bonding apparatus of claim 3,
wherein the rough adjustment device includes a rotary table on which the linearly moving mechanism is provided and a second driver configured to rotate the rotary table around the vertical axis, and
the linearly moving mechanism and the third holder held by the linearly moving mechanism are rotated around the vertical axis by rotating the rotary table with the second driver.

5. The bonding apparatus of claim 3, further comprising:
a striker inserted through a through hole formed through the third holder, and configured to press a central portion of the first substrate to allow the first substrate to come into contact with the second substrate.

6. The bonding apparatus of claim 3, comprising:
an imaging device configured to image a bonding surface of the first substrate; and
a controller,
wherein the controller performs a first imaging processing in which the bonding surface of the first substrate held by the third holder is imaged with the imaging device; a rough adjustment processing in which the third holder is rotated by controlling the rough adjustment device based on an imaging result obtained in the first imaging processing; a delivery processing in which the first substrate is delivered to the first holder by controlling the linearly moving mechanism to raise the third holder after the rough adjustment processing; a second imaging processing in which the bonding surface of the first substrate held by the first holder is imaged with the imaging device after the delivery processing; and a fine adjustment processing in which the first holder is rotated by controlling the at least one first driver based on an imaging result obtained in the second imaging processing after the second imaging processing.

7. The bonding apparatus of claim 1,
wherein the rough adjustment device includes:
a pre-alignment device configured to detect position information in the rotational direction of the first substrate before the first substrate is attracted and held by the first holder; and
a transfer arm configured to roughly adjust the position in the rotational direction of the first substrate based on the position information detected by the pre-alignment device.

8. The bonding apparatus of claim 1,
wherein the rough adjustment device includes:
an imaging device configured to image a bonding surface of the first substrate before the first substrate is attracted and held by the first holder; and
a transfer arm configured to roughly adjust the position in the rotational direction of the first substrate based on an imaging result obtained by the imaging device.

9. A bonding method, comprising:
attracting and holding a first substrate from above by using a first holder configured to attract and hold the first substrate from above;
attracting and holding a second substrate from below by using a second holder located lower than the first holder and configured to attract and hold the second substrate from below;
allowing, by using a moving mechanism configured to allow a first one of the first holder and the second holder to approach a second one of the first holder and the second holder, the first one of the first holder and the second holder to approach the second one of the first holder and the second holder;
roughly adjusting a position in a rotational direction of the first substrate before the first substrate is attracted and held by the first holder; and
finely adjusting the position in the rotational direction of the first substrate attracted and held by the first holder by using at least one first driver configured to drive the first holder by displacing a piezoelectric element.
